(19) United States
(12) Patent Application Publication
(10) Pub. No.: US 2011/0089570 A1
(43) Pub. Date: Apr. 21, 2011

(54) Multi-Layer Connection Cell

(75) Inventors: Romain Oddoart, Petit Mars (FR); Francois Abadie, Nantes (FR)

(73) Assignee: ATMEL NANTES S.A.S., Nantes Cedex 3 (FR)

(21) Appl. No.: 12/582,635

(22) Filed: Oct. 20, 2009

(51) Int. Cl. H01L 23/48; H01L 21/768

(52) U.S. Cl. 257/774; 438/667; 257/E23.01; 257/E21.575

(57) ABSTRACT

A semiconductor multi-layer connection cell is disclosed that includes configuration layers and “via” layers disposed between the configuration layers to allow configuration of signals at any layer in the connection cell. The layers include column structures extending through the layers. Each column structure includes a hole in a layer that can be filled to form an electrical connection between layers.

### TECHNICAL FIELD

This subject matter is generally related to microcontroller configuration using metal mask programmable features.

### BACKGROUND

Conventional fabrication techniques for microcontrollers use metal 1 layer configuration cells to encode a device configuration or setting. For example, consider a 32-bit “Device ID” configuration word located inside a microcontroller that is used by programming or debugging tools to identify the microcontroller model. The Device ID word can contain 4 bits describing the revision of a die. These 4 bits can be, for example, “0000” for the first revision of the silicon and can be incremented by one (e.g., from 0000 to 0001) for each new version of the silicon. The 4 revision bits can be programmed using 1-metal layer configuration cells. The metal wires that support a revision number can be connected to the outputs of the cells to provide the desired logic level. These conventional techniques can require fabrication of a new metal 1 layer mask each time a change is made to the configuration or setting, even if the change is simple, such as changing the polarity of a single bit.

### SUMMARY

A semiconductor multi-layer connection cell is disclosed that includes configuration layers and “via” layers disposed between the configuration layers to allow configuration of signals at any layer in the connection cell. The layers include column structures extending through the layers. Each column structure includes a hole in a layer that can be filled to form an electrical connection between layers.

### DESCRIPTION OF DRAWINGS

FIGS. 1A and 1B are top plan views illustrating example 1-metal layer connection cells having outputs that produce logic signals of opposite polarity.

FIGS. 2A-2C are top plan views illustrating an example 1-metal layer connection cell with holes that can be selectively filled to electrically connect the output of the cell.

FIGS. 3A-3D are side views of an example multi-layer connection cell with holes that can be selectively filled to electrically connect the output of the cell.

FIG. 4 is a side view of another example multi-layer connection cell with holes that can be selectively filled to configure any layer of the cell.

FIG. 5 is a side view of an example multi-layer connection cell which can be configured at any layer of the cell to provide signals of a desired polarity.

FIG. 6 is a flow diagram of a process of fabricating a multi-layer connection cell.

### DETAILED DESCRIPTION

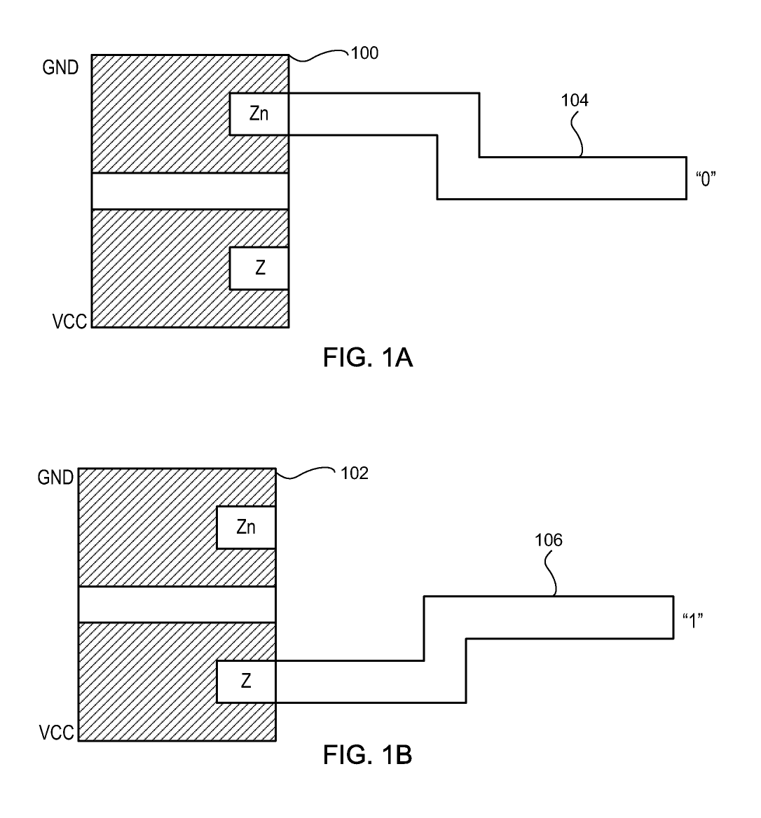

FIGS. 1A and 1B are top plan views illustrating examples of 1-metal layer connection cells 100, 102 having outputs 104, 106, respectively, that produce logic signals of opposite polarity. The connection cell 100 can be instantiated in a design so that output 104 (“Z”) provides a logic level “0,” and the connection cell 102 can be instantiated in the design so that the output 106 (“Zn”) provides a logic level “1.” During a place and route stage, the outputs 104, 106 can be automatically routed with metal wires using router software. For example, metal wires that support a revision number can be connected to the outputs 104, 106 to obtain the desired logic level “01.” A drawback to this approach is that the metal wires must be re-routed to change the polarity of the logic signals.

### Example Single-Layer Connection Cell

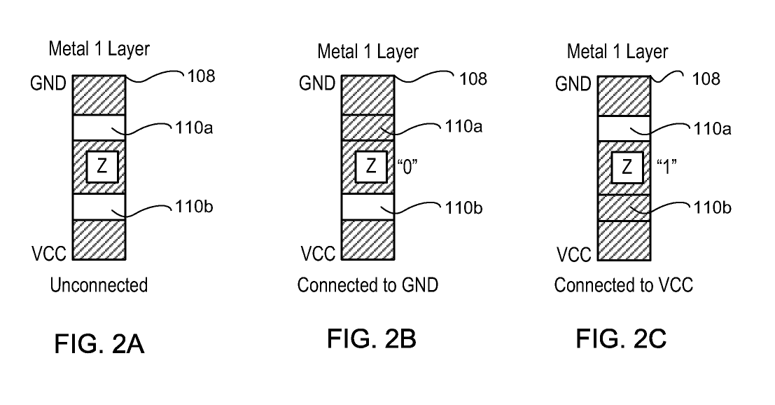

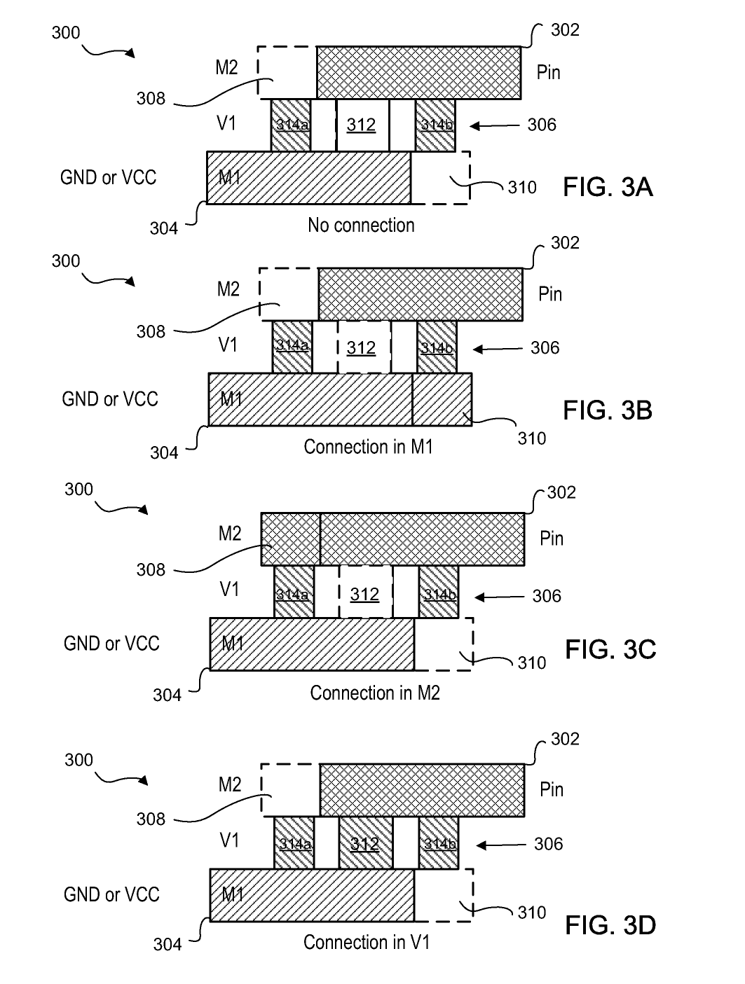

FIGS. 2A-2C are top plan views illustrating an example 1-metal layer connection cell 108 with holes 110a, 110b that can be selectively filled to electrically connect the output of the cell 108. FIG. 2A illustrates the metal 1 layer connection cell 108 with holes 110a, 110b unfilled, resulting in an unconnected state. FIG. 2B illustrates the metal 1 layer connection cell 108 with hole 110a filled and hole 110b unfilled, resulting in ground (GND) being connected to output “Z” and voltage (VCC) being unconnected from output “Z.” The resulting output “Z” is a logic signal “0.” FIG. 2C illustrates the metal 1 layer connection cell 108 with holes 110a unfilled and 110b filled, resulting in voltage VCC being connected to output “Z” and ground GND being unconnected from output “Z.” The resulting output “Z” is a logic signal “1.” This method can be extended to multi-layer connection cells by including “via” layers between configuration layers, as described in reference to FIGS. 3-5.

### Examples of Multi-Layer Connection Cells

FIGS. 3A-3D are side views of an example multi-layer connection cell with holes that can be selectively filled to electrically connect the output of the cell. In the example shown, a multi-layer connection cell 300 includes 3 layers: configuration layers 302, 304 and “via” layer 306. The configuration layer 302 includes a hole 308, the configuration layer 304 includes a hole 310 and the “via” layer 306 includes a hole 312 and column segments 314a, 314b. Although the configuration layers in this example are metal layers M1, M2, other types of layers can be used as configuration layers (e.g., poly layers). The description that follows will refer to configuration layers as metal layers to be consistent with the examples.

Referring to FIG. 3A, the connection cell 300 is shown in an unconnected configuration. In this configuration, the holes 308, 310 and 312 are not filled. Referring to FIG. 3B, the connection cell 300 is shown with a connection in the configuration layer 304. This connection is made by filling the hole 310 and leaving the hole 308 in configuration layer 304 unfilled and the hole 312 in “via” layer 306 unfilled. In this example, the connection provides either ground voltage (GND) or a supply voltage (VCC) on the configuration layer 304 to the configuration layer 302. In this example, a pin output of the cell 300 is in the configuration layer 302 (the M1 layer).

Referring to FIG. 3B, the connection cell 300 is shown with a connection in the configuration layer 304 (M1). This connection is made by filling the hole 310 in configuration layer 302, and leaving the hole 308 in the configuration layer 304 (M2) and the hole 312 in “via” layer 306 unfilled. The connection provides either GND or VCC on the configuration layer 304 to the configuration layer 302 through column segment 314b. Note that the dashed lines delineate the holes 308, 310, 312 as seen by a reader of, for example, place and route software.

Referring to FIG. 3C, the connection cell 300 is shown with a connection in the configuration layer 302. This connection is made by filling the hole 310 and leaving hole 308 in configuration layer 304 unfilled and the hole 312 in “via” layer 306 unfilled. The connection provides either GND or VCC on the configuration layer 304 to the configuration layer 302 through column segment 314a.

Referring to FIG. 3D, the connection cell 300 is shown with a connection in the “via” layer 306. This connection is made by filling the hole 312 in the “via” layer 306 and leaving the holes 310, 308 in the configuration layers 302, 304 unfilled. The connection provides either GND or VCC on the configuration layer 304 to the configuration layer 302.

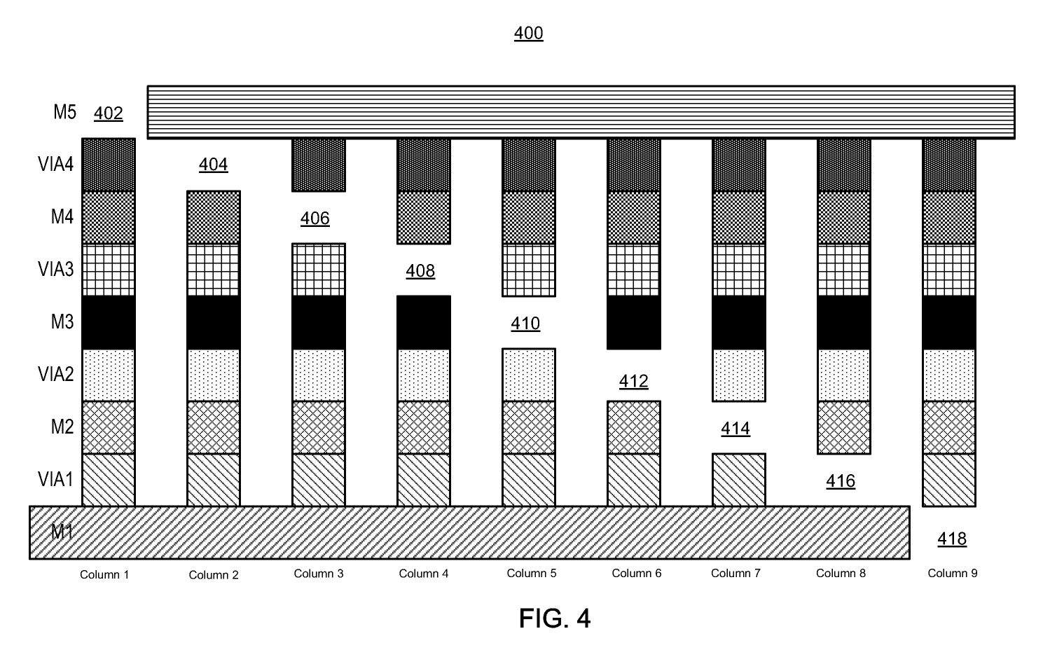

FIG. 4 is a side view of another example multi-layer connection cell with holes that can be selectively filled to configure any layer of the cell. In FIG. 4, the method of FIG. 3 is applied to a 5-metal layer cell 400. The cell 400 has 9 total layers: 5 metal layers M1-M5 and 4 “via” layers V1A1, V1A2, V1A3, and V1A4. The cell 400 is symmetrical to allow connections and disconnections to any voltage or ground in the cell 400.

In the 5-metal layer cell 400 there are 9 columns; one column for each layer in the cell 400. The columns are created in the cell 400 with a “hole” inside each column for each metal and via layer. The columns are represented in FIG. 4 by patterned segments to indicate the layers comprising the column and do not indicate any particular material. In this example, a pin output of the cell can be in the M1 layer and a voltage VCC or ground GND can be in the M5 layer. The holes 402-418 in the columns can be selectively filled to provide a desired connection or disconnection.

For example, the first column in the cell 400 includes 8 layers and a hole 402 in metal layer M5. An electrical connection can be made in M5 to connect layers M1 and M5 by filling hole 402 with conductive material and leaving the other holes 404-418 in the cell 400 unfilled. If M5 includes an output pin and M1 is VCC or GND, then the result would be VCC or GND applied to the output pin.

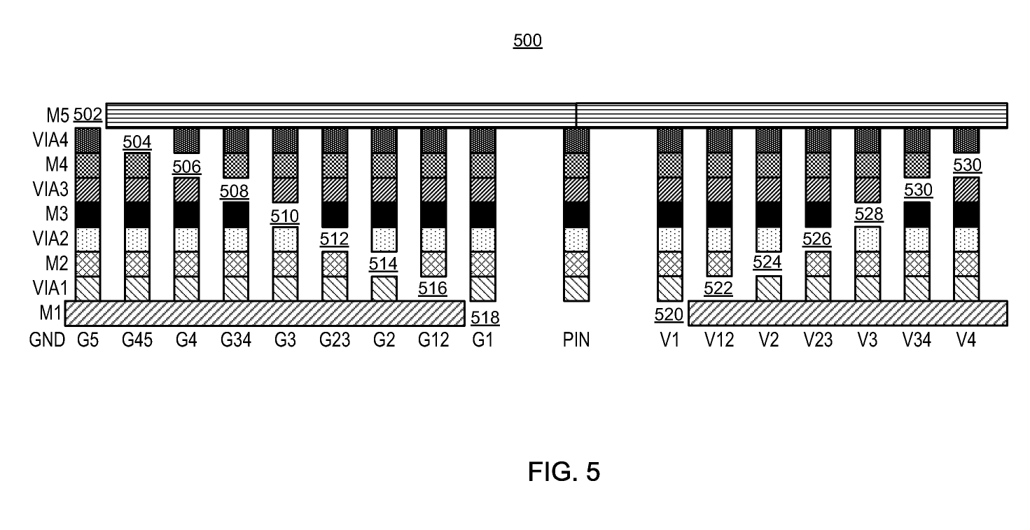

Similarly, electrical connections or signal configurations can be made in any layer of the cell 400 to connect layers M1 and M5 by filling a hole in a column for the layer for which an electrical connection is desired to be made. For example, filling the hole 404 will result in an electrical connection in the VIA4 layer, filling the hole 406 will result in an electrical connection in the M4 layer, filling the hole 408 will result in an electrical connection being made in the VIA3 layer and so forth. The cell 400 can be used as a building block for other multi-layer connection cell configurations, such as the multi-layer connection cell 500, as described in reference to FIG. 5.

FIG. 5 is a side view of an example multi-layer connection cell 500 which can be configured at any layer of the cell to provide signals of a desired polarity. The cell 500 is generally formed from two cells having the structure of cell 400. Like the cell 400, the cell 500 includes a total of 9 layers: 5 metal layers M1-M5 and 4 “Via” layers V1A1, V1A2, V1A3, and V1A4. An additional column has been added to the center of the cell 500 to provide electrical connection to an output pin in each layer of the cell 500.

The left half of the cell 500 includes a number of spaced apart columns. In this example, there are 9 columns or one column for each layer of the left side of cell 500. The left half of the cell 500 can be configured to make electrical connections between ground voltages G1-G5 and an output pin of the cell 500 by way of the M5 layer. For example, filling a hole 502 will result in an electrical connection in the M5 layer, thereby connecting ground G5 to the pin by way of the M5 layer. Filling a hole 504 will result in an electrical connection in the VIA4 layer, thereby connecting ground G45 to the pin by way of the M5 layer. Filling a hole 506 will result in an electrical connection being made in the M4 layer, thereby connecting ground G4 to the pin by way of the M5 layer. This pattern of selectively filling holes can be done for any of the holes 502-518 to electrically connect a ground voltage to the pin by way of the M5 layer.

The right half of the cell 500 also includes a number of spaced apart columns. In this example, there are 9 columns or one column for each layer of right side of the cell 500. The right half of the cell 500 can be configured to make electrical connections between voltages V1-V4 and an output pin of the cell 500 by way of the M5 layer. For example, filling a hole 530 will result in an electrical connection in the M4 layer, thereby connecting voltage V4 to the pin by way of the M5 layer. Filling a hole 530 will result in an electrical connection in the VIA3 layer, thereby connecting voltage V34 to the pin by way of the M5 layer. Filling a hole 528 will result in an electrical connection being made in the M3 layer, thereby connecting voltage V3 to the pin by way of the M5 layer. This pattern of selectively filling holes can be done for any of the holes 520-530 to electrically connect a voltage to the pin by way of the M5 layer.

### Example Process Flow

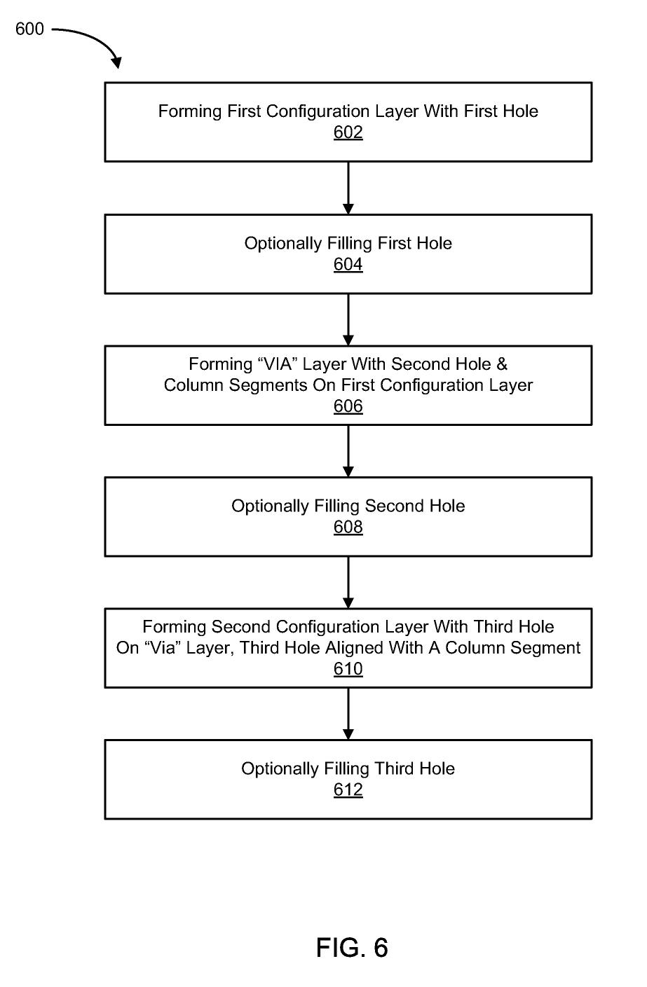

FIG. 6 is a flow diagram of a process 600 of fabricating a multi-layer connection cell. The process 600 can use standard semiconductor process technology. The process 600 can begin by forming a first configuration layer including a first hole extending through the first configuration layer (602). The first hole is optionally filled with conductive material (604).

A “via” layer is formed on the first configuration layer (606). The “via” layer includes spaced-apart column segments and a second hole extending through the “via” layer. A first column segment in the “via” layer is aligned with the first hole in the first configuration layer. The second hole is optionally filled with conductive material (608).

A second configuration layer is formed on the “via” layer (610). The second configuration layer includes a third hole extending through the second configuration layer. The third hole is aligned with a second column segment in the “via” layer. The third hole is optionally filled with conductive material (612).

The process 600 described above can be repeated for n-layers in a n-layer connection cell. The number of via layers is equal to n−1. Each layer in the cell includes a single hole for a total of n holes. Each layer in the cell includes a number of column segments equal to two times the total number of via layers. The resulting cell structure includes n spaced apart columns. Each column includes a single hole and n−2 column segments. Each hole can optionally be filled to form an electrical connection between two layers. For example, a 6 layer connection cell (n=6) in an unconnected state includes 11 total layers: 6 configuration layers and 5 via layers. Each layer in the cell includes 9 column segments and there are 11 columns in the cell.

While this document contains many specific implementation details, these should not be construed as limitations on the scope what may be claimed, but rather as descriptions of features that may be specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

What is claimed is:

1. A semiconductor multi-layer connection cell, comprising:
a first configuration layer including a first hole extending through the first configuration layer;
a via layer formed on the first configuration layer, the first via layer including a second hole and spaced apart column segments extending through the via layer; and
a second configuration layer formed on the via layer, the second configuration layer including a third hole extending through the second configuration layer,
where the first and third holes are aligned with column segments in the via layer to allow electrical connection between the configuration layers through the via layer.

2. The cell of claim 1, where at least one configuration layer is a metal layer.

3. The cell of claim 2, where the first configuration layer provides a voltage and the second configuration layer is connected to an output of the cell.

4. The cell of claim 2, where the voltage is a ground voltage.

5. The cell of claim 1, where one of the first, second and third holes is filled with conductive material to form an electrical connection between the configuration layers through the via layer.

6. A semiconductor multi-layer connection cell, comprising:
a number of configuration layers and via layers, where a via layer is disposed between each pair of adjacent configuration layers; and
a number of spaced apart column structures extending through the layers, each column structure including a hole in a layer, the hole for receiving conductive material to form an electrical connection between layers through the column.

7. The cell of claim 6, where at least one configuration layer is a metal layer.

8. The cell of claim 6, where at least one configuration layer provides a voltage.

9. The cell of claim 8, where the voltage is a ground voltage.

10. The cell of claim 6, where one of the first, second and third holes is filled with conductive material to form an electrical connection between the configuration layers through the via layer.

11. A method of fabricating a semiconductor multi-layer connection cell, the method comprising:
forming a first configuration layer with a first hole;
forming a via layer on the first configuration layer, the via layer including a second hole and column segments, where a first column segment in the via layer is aligned with the first hole; and
forming a second configuration layer on the via layer, the second configuration layer including a third hole aligned with a second column segment in the via layer.

12. The method of claim 11, where one of the first, second and third holes is filled with electrically conductive material.

13. The method of claim 11, where at least one configuration layer is a metal layer.

14. The method of claim 11, where at least one configuration layer provides a voltage.

15. The method of claim 14, where the voltage is a ground voltage.

16. A method of fabricating a semiconductor multi-layer connection cell, comprising:
forming a number of configuration layers and via layers, where a via layer is disposed between each pair of adjacent configuration layers; and
forming a number of spaced apart column structures extending through the layers, each column structure including a hole in a layer, the hole for receiving conductive material to form an electrical connection between layers through the column.

17. The method of claim 16, where at least one configuration layer is a metal layer.

18. The method of claim 16, where at least one configuration layer provides a voltage.

19. The method of claim 18, where the voltage is a ground voltage.

20. The method of claim 16, where one of the first, second and third holes is filled with conductive material to form an electrical connection between the configuration layers through the via layer.
